(19) United States
(12) Patent Application Publication
(10) Pub. No.: US 2023/0275401 A1
(43) Pub. Date: Aug. 31, 2023

(54) SEMICONDUCTOR LASER DEVICE AND METHOD OF MANUFACTURING THE SAME

(71) Applicant: Ushio Denki Kabushiki Kaisha, Tokyo (JP)

(72) Inventors: Shintaro Miyamoto, Tokyo (JP); Seiji Kitamura, Tokyo (JP)

(73) Assignee: Ushio Denki Kabushiki Kaisha, Tokyo (JP)

(21) Appl. No.: 18/101,078

(22) Filed: Jan. 24, 2023

(30) Foreign Application Priority Data
Feb. 25, 2022 (JP) 2022-028541

(51) Int. Cl. H01S 5/22; H01S 5/343; H01S 5/028

(52) U.S. Cl. CPC H01S 5/22; H01S 5/3436; H01S 5/028

(57) ABSTRACT

A semiconductor laser device includes a laser resonator including a layered structure in which a lower cladding layer, an active layer, and an upper cladding layer are formed over a semiconductor substrate, and a ridge that is formed on the upper cladding layer. The laser resonator emits laser light having a beam profile. When viewed in plan from a direction orthogonal to the semiconductor substrate, the laser resonator has an emission area on its emission end face. When the emission end face of the laser resonator is viewed in front, a virtual line defined by the intensity being 1/e₂ of the peak intensity of the beam profile of the laser light fits inside the upper cladding layer in the emission area.

### CROSS-REFERENCE TO RELATED APPLICATION(S)

This application claims priority from Japanese Patent Application No. 2022-028541 filed on Feb. 25, 2022. The entire teachings of the above application are incorporated herein by reference.

### BACKGROUND

### Technical Field

The present disclosure relates to a semiconductor laser device.

### Description of the Related Art

Semiconductor lasers (LDs) are used as light sources for laser pointers. In particular, red and infrared LDs have been often used as a light source for pointers, and blue and green LDs are also used. In recent years, there has been an increasing demand to further make the light point of a pointer clearly visible or recognizable with sensors or cameras.

A semiconductor laser device has been known to have a structure with a ridge in the p-type cladding layer in semiconductor lasers used for optical pickup devices and the like.
Patent literature 1: JP-A-2010-080867
Patent literature 2: JP-A-2008-187068
Patent literature 3: JP-A-2000-133877

### SUMMARY OF THE INVENTION

When the present inventors observed the far-field pattern (FFP, far-field image), which is an image at a point that is irradiated with a semiconductor laser, they recognized a problem that the desired point could not be irradiated with the laser beam with sufficient focus because interference fringes occur around the periphery of the beam, specifically on the side of the beam.

After examining this problem, the present inventors have come to recognize that the cause of the problem originates from the insulating layer (SiO₂ film) of the semiconductor laser device. That is, the SiO₂ layers are provided on the side face of the ridge and the front face of the p-type cladding layer of the semiconductor laser device. Laser light seeping into the SiO₂ insulating layer in the vicinity of the ridge causes interference in the SiO₂ film, which in turn generates interference fringes in the FFP. The same problem also occurs on materials, such as oxide, nitride, and oxynitride in addition to SiO₂, that have insulation properties and allow light to transmit or reflect. This recognition has not been taken as the general knowledge of those skilled in the art; however, it is the unique recognition of the present inventors.

Certain aspects of the present disclosure are made under such circumstances, and one of the exemplary purposes of the present disclosure is to provide a semiconductor laser that suppresses the generation of interference fringes in the FFP.

One aspect of the present disclosure relates to an edge-emitting semiconductor laser device. The semiconductor laser device includes a laser resonator including a layered structure in which a lower cladding layer, an active layer, and an upper cladding layer are formed over a semiconductor substrate, and a ridge that is formed on the upper cladding layer. The laser resonator emits laser light having a beam profile. When viewed in plan from a direction orthogonal to the semiconductor substrate, the laser resonator includes an emission area on its emission end face. When the emission end face of the laser resonator is viewed in front, a virtual line defined by the intensity being 1/e₂ of the peak intensity of the beam profile of the laser light fits inside the upper cladding layer in the emission area.

Another aspect of the present disclosure relates to a method of manufacturing an edge-emitting semiconductor laser device. The manufacturing method includes forming a layered structure of a lower cladding layer, an active layer, and an upper cladding layer over a semiconductor substrate, undergoing ridge processing in the upper cladding layer in a manner that, when the emission end face of the laser resonator is viewed in front, a virtual line defined by the intensity being 1/e₂ of the peak intensity of the beam profile of laser light fits inside the upper cladding layer in the emission area, and forming an insulating layer covering at least a side face of the ridge that has been formed on the upper cladding layer by the ridge processing.

Note that any combination of the above components, or mutual substitution of components or expressions among methods, devices, systems, etc., is also valid as an aspect of the present invention or disclosure. Furthermore, the description of this item (SUMMARY OF THE INVENTION) does not describe all the indispensable features of the present invention; hence, the sub-combinations of these features described can also be the present invention or disclosure.

An aspect of the present disclosure is capable of suppressing the generation of interference fringes in the FFP.

### BRIEF DESCRIPTION OF DRAWINGS

FIG. 1 is a perspective view of a semiconductor laser device according to Embodiment 1.

FIG. 2 is a plan view of the semiconductor laser device in FIG. 1.

FIG. 3A is a cross-sectional view of the semiconductor laser device taken along the line 3A-3A in FIG. 2.

FIG. 3B is a cross-sectional view of the semiconductor laser device taken along the line 3B-3B in FIG. 2.

FIG. 4 is a schematic diagram illustrating a variation in a beam spot diameter.

FIGS. 5A to 5E are diagrams illustrating the method of manufacturing the semiconductor laser device.

FIG. 6 is a plan view of the semiconductor laser device according to Variation Example 1.1.

FIG. 7 is a perspective view of a semiconductor laser device according to Embodiment 2.

FIG. 8 is a front view of the semiconductor laser device of FIG. 7 when viewed from its emission end face.

FIG. 9 is a perspective view of a semiconductor laser device according to Embodiment 3.

FIG. 10 is a front view of the semiconductor laser device of FIG. 9 when viewed from its emission end face.

FIG. 11 is a perspective view of a semiconductor laser device according to Embodiment 4.

FIG. 12 is a plan view of the semiconductor laser device in FIG. 11.

FIG. 13 is a plan view of a semiconductor laser device 100Da according to Variation Example 4.1.

FIG. 14 is a front view of a semiconductor laser device according to Embodiment 5 when viewed from its emission end face.

### DETAILED DESCRIPTION OF THE EMBODIMENTS

### Overview of the Embodiments

Hereinafter, an overview of some exemplary embodiments of the present disclosure will be described. This overview is intended as a preface to the detailed description that follows, or for a basic understanding of the embodiments. The overview describes some concepts of one or more embodiments in a simplified manner and is not intended to limit the scope of the invention or disclosure. In addition, the overview is not a comprehensive overview of all conceivable embodiments, nor does it limit the indispensable components of embodiments. For convenience, “an embodiment” may be used to refer to one embodiment (Example or Variation Example) or a plurality of embodiments (Examples or Variation Examples) disclosed in the present specification.

### Summary of Embodiment

A semiconductor laser device according to one embodiment is an edge-emitting semiconductor laser device. The semiconductor laser device includes a laser resonator including a layered structure in which a lower cladding layer, an active layer, and an upper cladding layer are formed over a semiconductor substrate, and a ridge that is formed on the upper cladding layer. The laser resonator emits laser light having a beam profile. When viewed in plan from a direction orthogonal to the semiconductor substrate, the laser resonator includes an emission area on its emission end face. When the emission end face of the laser resonator is viewed in front, a virtual line defined by the intensity being 1/e₂ of the peak intensity of the beam profile of the laser light fits inside the upper cladding layer in the emission area.

In this configuration, the ridge is formed to expand in a width direction in the vicinity of the emission end face in a manner of having a sufficiently large cross section with respect to the beam diameter. Since 95% of the total light intensity is contained within a 1/e₂ width of the beam, the intensity of light leaking from the upper cladding layer is smaller than 5% of the total light intensity. This suppresses light in the emission area from leaking from the upper cladding layer to the side. Therefore, this suppresses the beam emitted from the side of the upper cladding layer, suppressing the generation of interference fringes in the FFP.

In one embodiment, when the semiconductor laser device is viewed in plan from a direction orthogonal to the semiconductor substrate, the width of the ridge may widen at the boundary of the emission area, and the shape of the ridge may have a step shape, for example. This configuration can suppress the spread of the beam in the emission area.

In one embodiment, at least the side face of the ridge may be covered with an insulating layer. When the side face of the ridge of the upper cladding layer is covered with the insulating layer, light leaking into the insulating layer is emitted from the edge face of the insulating layer. The above configuration suppresses light leaking into the insulating layer, thereby suppressing the generation of interference fringes in the FFP.

In one embodiment, when the emission end face of the laser resonator is viewed in front, the cross-sectional shape of the ridge in the emission area of the laser resonator may be rectangular, and the width of the ridge may be larger than the 1/e² width of the beam profile in the lateral direction.

In one embodiment, the width of the ridge may be three times or more as large as the 1/e² width of the beam profile in the lateral direction. Since 99.97% of the total light intensity is contained within three times the beam 1/e² width of the beam profile, light leaking from the upper cladding layer is smaller than 0.03% of the total light intensity. This further suppresses interference fringes in the FFP.

In one embodiment, the width of the ridge may be four times or more as large as the 1/e² width of the beam profile in the lateral direction. In this case, light leaking from the upper cladding layer is smaller than 0.02% of the total light intensity. In one embodiment, the width of the ridge may be five times or more as large as the 1/e² width of the beam profile in the lateral direction. In this case, light leaking from the upper cladding layer is smaller than 0.01% of the total light intensity. For practical use, three times is sufficient; however, when a sharper FFP is desired, the width of the rectangular upper cladding layer in the emission area may be designed to be increased to four times as large as the 1/e² width, preferably 5 times or more.

In one embodiment, when the emission end face of the laser resonator is viewed in front, the width of the upper end of the ridge in the emission area may be narrower than the width of the lower end of the ridge.

In one embodiment, when the emission end face is viewed in front, the cross-sectional shape of the ridge in the emission area may have a lower rectangular portion having a first width and an upper rectangular portion having a second width narrower than the first width and being adjacent to and above the lower rectangular portion. The first width may be larger than the 1/e² width of the beam profile in the lateral direction. In the longitudinal direction, the laser resonator has a waveguide structure in which a core layer is sandwiched by cladding layers, thus the beam spreads smaller in the longitudinal direction than in the lateral direction. Hence, expanding the width (first width) of the lower rectangular portion, which is the rise of the ridge, suppresses light leaking in the lateral direction.

In one embodiment, the first width may be three times or more as large as the 1/e² width of the beam profile in the lateral direction. The first width may be four times or more as large as the 1/e² width of the beam profile in the lateral direction or may be five times or more as large as the width thereof.

In one embodiment, when the emission end face of the laser resonator is viewed in front, the cross-sectional shape of the ridge in the emission area may be tilted from the upper end to the lower end. This tilt can be formed by using the isotropic nature of wet etching.

In one embodiment, the insulating layer may include at least one material selected from the group consisting of SiO₂, SiNₓ, SiON, Al₂O₃, AlN, AlON, Ta₂O₅, and ZrO₂.

In one embodiment, the active layer may include at least one material selected from the group consisting of In, Ga, Al, As, P, and N.

In one embodiment, when the semiconductor laser device is viewed in plan from a direction orthogonal to the semiconductor substrate, the laser resonator may include a gain area adjacent to the emission area. The ridge in the gain area of the laser resonator may be designed such that the laser light has a transverse single mode.

In one embodiment, a light-shielding groove is formed at a location adjacent to the emission area or in the emission area of the semiconductor laser device, the light-shielding groove extending in a direction orthogonal to the laser resonator.

An edge-emitting semiconductor laser device according to one embodiment includes a laser resonator including a layered structure in which a lower cladding layer, an active layer, and an upper cladding layer are formed over a semiconductor substrate, and a ridge that is formed on the upper cladding layer. When viewed in plan from a direction orthogonal to the semiconductor substrate, the laser resonator includes an emission area on its emission end face and a gain area adjacent to the emission area. The width of the ridge of the upper cladding layer widens stepwise at the boundary between the gain area and the emission area, and the width of the ridge in the emission area is three times or more as large as the maximum width of the ridge in the gain area.

### Embodiment

Hereinafter, the present disclosure will be described with reference to the drawings based on suitable embodiments. Identical or equivalent components, members, and processes shown in the respective drawings are marked with the same symbols, and duplicated explanations are omitted as appropriate. The embodiments are intended to be exemplary rather than to limit the disclosure, and all features and combinations thereof described in the embodiments are not necessarily essential to the disclosure.

The dimensions (thickness, length, width, etc.) of each member described in the drawings may be scaled as appropriate for ease of understanding. Furthermore, the dimensions of a plurality of members do not necessarily represent their size relationship; although one member A is drawn thicker than another member B on the drawing, the member A may be thinner than the member B.

### Embodiment 1

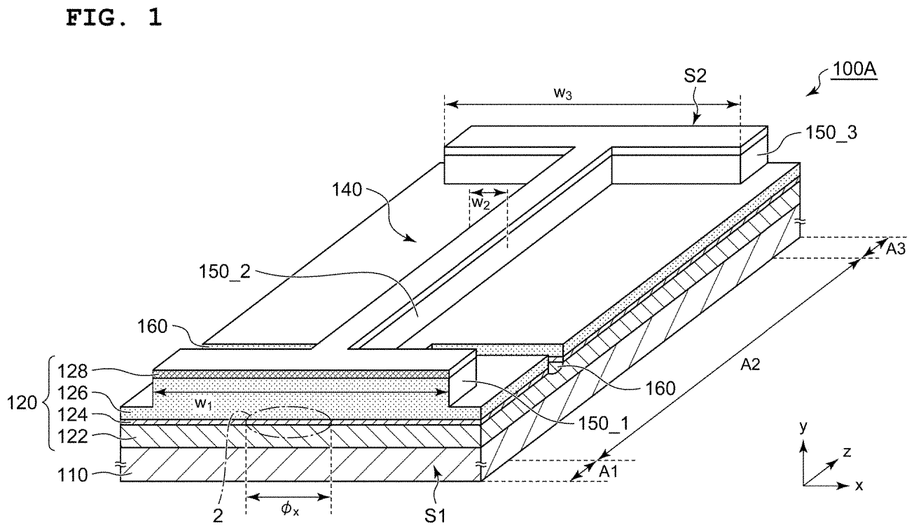

FIG. 1 is a perspective view of a semiconductor laser device 100A according to Embodiment 1. The semiconductor laser device 100A is of edge-emitting type and emits a laser light (beam) from an emission end face S1. A laser resonator 140 is formed between the emission end face S1 and a reflection end face S2 of the semiconductor laser device 100A. S1 and S2 are also referred to as a front end face and a rear end face, respectively.

The laser resonator 140 is formed on the semiconductor substrate 110. The laser resonator 140 includes a layered structure (multi-layered growth layer) 120 in which a lower cladding layer 122 that is an n-type cladding layer, a light-emitting layer 124 that is an active layer, an upper cladding layer 126 that is a p-type cladding layer, and a p-type contact layer 128 are formed. The upper cladding layer 126 is formed with a ridge 150 for current constriction through ridge processing. The ridge 150 includes a ridge 150_1, a ridge 150_2, and a ridge 150_3. At least the side face of the ridge 150 is covered with an insulating film, which is omitted in FIG. 1. Electrodes are necessary for the operation of the laser resonator 140; however, they are omitted in the figure because they can be formed at appropriate locations using known technology.

In the figure, the x-axis denotes a direction of the width of the laser resonator 140, the y-axis denotes a direction perpendicular to the semiconductor substrate 110, and the z-axis denotes a direction of the length of the laser resonator 140, i.e., the waveguide direction of the laser beam. In the present specification, viewing the laser resonator 140 from plan means viewing the laser resonator 140 in plan from a direction orthogonal to the semiconductor substrate 110, i.e., viewing the laser resonator 140 along the y-axis. In addition, viewing the emission end face S1 of the laser resonator 140 from front means viewing the laser resonator 140 along the z-axis.

When the laser resonator 140 is viewed in plan, the laser resonator 140 includes a plurality of areas A1 to A3 adjacent in this order in the z-axis direction. The area A1 including the emission end face S1 is referred to as the emission area. The area A2 adjacent to the emission area A1 is referred to as the gain area. The area A3 having the reflection end face S2 is referred to as the reflection area. The ridges 150_1, 150_2, and 150_3 of the upper cladding layer 126 in the emission area A1, the gain area A2, and the reflection area A3 have different widths w₁, w₂, and w₃, respectively. Specifically, the width w₁ of the ridge 150_1 in the emission area A1 is sufficiently wider than the width w₂ of the ridge 150_2 in the gain area A2.

Note that making the width w₃ of the ridge 150_3 in the reflection area A3 equal to the width w₁ of the ridge 150_1 can maintain the continuity of the laser resonator even when a dicing line (cleavage surface) is shifted during the process of cutting out the semiconductor laser device 100A from the wafer.

The shape of the ridge 150_2 in the gain area A2 determines a horizontal transverse mode of the laser beam. The ridge 150_2 is designed such that the laser beam guided thereinside has a single horizontal transverse mode. The width w₂ of the ridge 150_2 can be about 2 μm, and its length can be approximately 1500 μm, for example.

A light-shielding groove 160 extending in the x-axis direction kept away from the ridge 150 is formed in an area close to the emission area A1 and also in the gain area A2.

FIG. 1 schematically illustrates a beam profile of the laser beam when the emission end face S1 of the laser resonator 140 is viewed in front. Specifically, the beam profile is shown with a virtual line 2 along which the intensity of the beam profile is 1/e² of the peak thereof. The maximum width of the virtual line 2 is referred to as the 1/e² width, which refers to a spot diameter of the Gaussian beam. The spot diameter at the emission end face S1 is referred to as an emission spot diameter ϕₓ. The beam profile of the laser beam at the emission end face S1 is also referred to as NFP (near field pattern).

In the present embodiment, the width w₁ of the ridge 150 in the emission area A1 of the laser resonator 140 is determined such that the virtual line 2 above the light-emitting layer 124 fits in the upper cladding layer 126 in the emission area A1, in other words, the upper half of the virtual line 2 avoids extending beyond the upper cladding layer 126. Specifically, the width w₁ of the ridge 150_1 in the emission area A1 is larger than the emission spot diameter ϕₓ.

In the present embodiment, when the emission end face S1 of the laser resonator 140 is viewed in front, the ridge 150 of the upper cladding layer 126 in the emission area A1 of the laser resonator 140 has a rectangular cross-sectional shape. Hence, the width w₁ of the ridge 150_1 is the width of a rectangle.

The width w₁ of the rectangular ridge 150_1 is preferably 3 times or more as large as the emission spot diameter ϕₓ. The width w₁ of the rectangular ridge 150_1 is more preferably 4 times or more as large as the emission spot diameter ϕₓ and further preferably 5 times or more as large as the emission spot diameter ϕₓ.

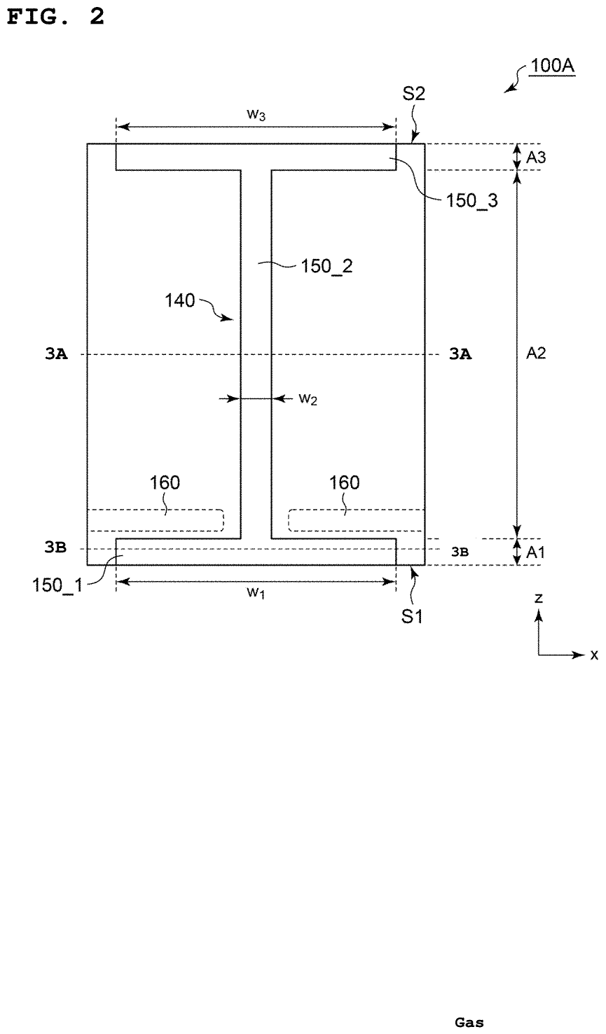

FIG. 2 is a plan view of the semiconductor laser device 100A of FIG. 1. When the semiconductor laser device 100A is viewed in plan, the width of the ridge 150 expands stepwise at the boundary between the emission area A1 and the gain area A2.

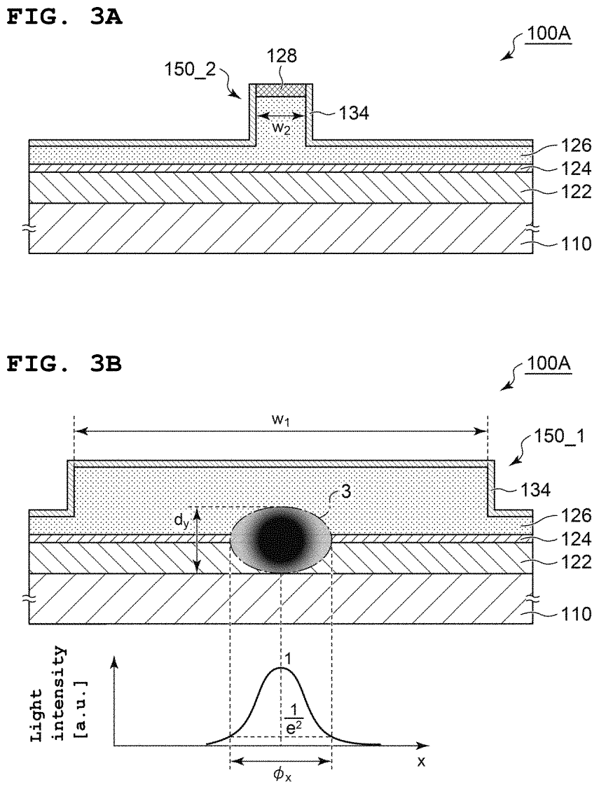

FIG. 3A is a cross-sectional view of the semiconductor laser device 100A taken along the line 3A-3A in FIG. 2. FIG. 3B is a cross-sectional view of the semiconductor laser device taken along the line 3B-3B in FIG. 2. The side faces of the ridges 150_1 and 150_1 of the upper cladding layer 126 are covered with an insulating film 134.

In FIG. 3A, a p-type contact layer 128 is formed on the upper side of the ridge 150_2 of the upper cladding layer 126. In contrast, in FIG. 3B, no p-type contact layer 128 is formed on the upper side of the ridge of the upper cladding layer 126, and the insulating film 134 is formed instead. In other words, the emission area A1 is considered to be a current non-injection area and has no gain.

The disclosure is not limited to this embodiment; the p-type contact layer 128 may be formed on the upper side of the ridge 150_1 even in the emission area A1, as is similar to in the gain area A2, and the insulating film 134 may be formed on the p-type contact layer 128.

The lower part of FIG. 3B illustrates the optical intensity distribution of the laser beam in the x-axis direction. A contour line corresponding to the 1/e₂ width is indicated as a virtual line 3 in the cross-sectional view. The width of the virtual line 3 in the x direction can be understood as the spot diameter ϕₓ of the Gaussian beam in the x direction, and the height of the virtual line 3 in the y direction can be understood as a spot diameter d_{y} of the Gaussian beam in the y direction.

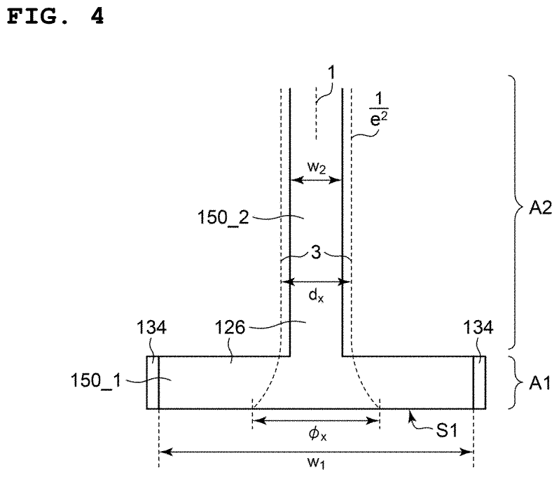

FIG. 4 is a schematic diagram illustrating the variation of a beam spot diameter dₓ. FIG. 4 illustrates the semiconductor laser device 100A viewed in plan from above. The spot diameter dₓ in the gain area A2 is determined by the width w₂ of the ridge 150_2. After entering the emission area A1 from the gain area A2, the laser beam expands as it is guided toward the emission end face S1. The spot diameter dₓ is smaller at a location closer to the gain area A2 and larger at a location closer to the emission end face S1. The spot diameter dₓ at the emission end face S1 is the emission spot diameter ϕₓ shown in FIG. 1.

As mentioned above, the width w₁ of the ridge 150_1 is larger than the emission spot diameter ϕₓ (ϕₓ<w₁) at the emission end face S1. Since dₓ≤ϕₓ is always true in the emission area A1, dₓ<w₁ is always true in the emission area A1. In other words, most of the laser beam is guided without leaking out from the upper cladding layer 126 to the insulating film 134 in the emission area A1.

In this configuration, the ridge 150_1 in the emission area A1 is formed in the width direction (x-axis direction) in a manner of having a sufficiently large cross section with respect to the emission spot diameter ϕₓ. Since 95% of the total light intensity is contained in the 1/e₂ width of the beam, the light leaking from the upper cladding layer 126 to the insulating film 134 is smaller than 5% of the total light intensity. Hence, this configuration suppresses the light leaking from the upper cladding layer 126 to the insulating film 134 on the side in the emission area A1. This suppresses the beam emitted from the side of the upper cladding layer 126, suppressing the generation of interference fringes in the FFP.

With respect to the optical intensity distribution of the laser beam, 99.9% of the total light intensity is contained in a range of three times the 1/e₂ beam width. Hence, when the width w₁ of the rectangular ridge 150_1 is set to be three times or more as large as the emission spot diameter ϕₓ, the light leaking from the upper cladding layer 126 is smaller than 0.03% of the total light intensity. This further suppresses interference fringes in the FFP.

Similarly, with respect to the optical intensity distribution of the laser beam, 99.98% of the total light intensity is contained in a range of four times the 1/e₂ beam width. Hence, when the width w₁ of the rectangular ridge 150_1 is set to be four times or more as large as the emission spot diameter ϕₓ, the light leaking from the upper cladding layer 126 is smaller than 0.02% of the total light intensity. In addition, 99.99% of the total light intensity is contained in a range of five times the 1/e₂ beam width. Hence, when the width w₁ of the rectangular ridge 150_1 is set to be five times or more as large as the emission spot diameter ϕₓ, the light leaking from the upper cladding layer 126 is smaller than 0.01% of the total light intensity. Hence, setting the width w₁ of the rectangular ridge 150_1 to be larger further suppresses light leaking to the side face. For practical use, it is sufficient that the width w₁ of the rectangular ridge 150_1 is 3 times as large as the 1/e₂ beam width; however, when sharper FFP is desired, it is recommended to design the width of the rectangular upper cladding layer in the emission area 4 times or more, preferably 5 times or more, as large as the 1/e₂ beam width. In edge-emitting semiconductor lasers, the beam shape (spot diameter) at the emission end face has typically a larger dimension in the x-axis direction, which is a direction of the epitaxially grown plane, than that in the y-axis direction, which is a stacking direction. The dimension of the spot diameter d_{y} in the y-axis direction is sufficiently small compared to the thickness of the cladding layer 126.

The configuration of the semiconductor laser device 100A has been described with focusing on the relationship between the width w₁ of the ridge 150_1 in the emission area A1 and the emission spot diameter ϕₓ; however, the characteristics of the semiconductor laser device 100A can also be described from the relationship between the width w₁ of ridge 150_1 in the emission area A1 and the width w₂ of ridge 150_2 in the gain area A2.

The emission spot diameter ϕₓ is highly dependent on the width w₂ of the ridge 150_2 in the gain area A2. However, when the width w₁ of the emission area A1 is wide as shown in the configuration of the present disclosure, the light will travel in a direction in which the width of the ridge is wider than the width w₂ specified in the gain region A2. In other words, when the length of the emission area A1 in the direction of the resonator is longer, the emission spot diameter ϕₓ is larger than the width w₂ of ridge 150_2. In contrast, when the length of the emission area A1 in the direction of the resonator is longer, the non-gain area becomes longer for the semiconductor laser device, resulting in poor light-emitting efficiency. In the present disclosure, the emission spot diameter ϕₓ estimated from the length of emission area A1 in the direction of the resonator is twice or less as large as the width w₂, and at most, it does not exceed 3 times. In other words, designing the ridges 150_1 and 150_2 in a manner of satisfying w₁>w₂×3 suppresses the laser light from leaking in the lateral direction in the emission area A1.

In other words, designing the ridges 150_1 and 150_2 to satisfy w₁>w₂×k with using k (k≥3) as a parameter further suppresses laser light from leaking in the lateral direction in the emission area A1. Making k larger such as 4, 5, . . . 10 further suppresses interference fringes.

Note that the width w₁ of the ridge 150_1 in the emission area A1 can be considered as a width w_{L} in the case of Embodiments 2 to 4.

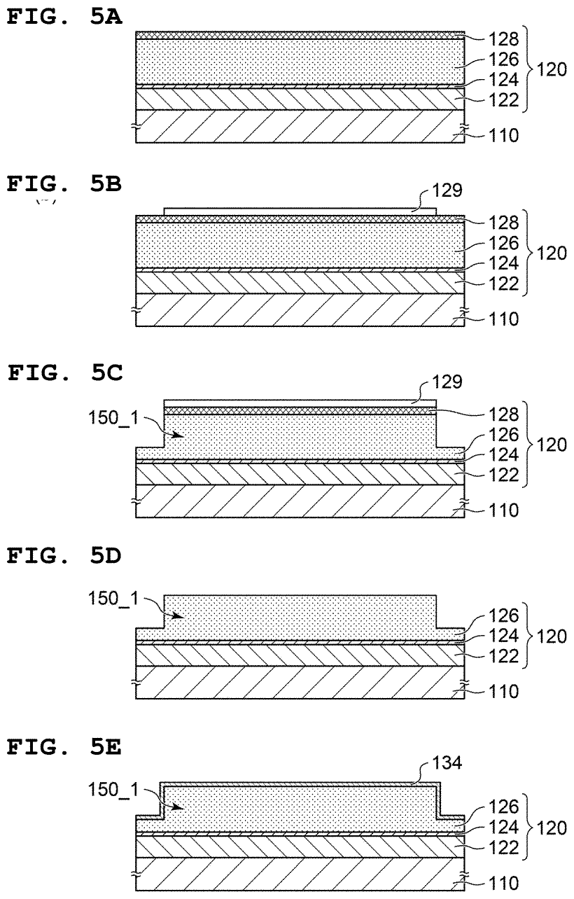

Hereinafter, the manufacturing method of the semiconductor laser device 100A will now be described. FIGS. 5A to 5E are diagrams illustrating the method of manufacturing the semiconductor laser device 100A. Here, the method of manufacturing the semiconductor laser device 100A is described with focusing on the cross-sectional view (the emission area A1) thereof taken along the line 3B-3B in FIG. 2.

Referring to FIG. 5A, the semiconductor substrate 110 is, for example, an n-GaAs substrate. A multi-layered growth layer 120 is formed over the upper surface (front surface) of the semiconductor substrate 110 by the MOCVD (metal organic chemical vapor deposition) method. The multi-layered growth layer 120 includes the lower cladding layer 122, the light-emitting layer 124, the upper cladding layer 126, and the p-type contact layer 128.

The lower cladding layer 122 is, for example, an n-type cladding layer made of AlGaInP or AlGaAs having a thickness of 2.0 μm, for example.

The light-emitting layer 124 is an active layer having a quantum well structure. The active layer includes, for example, a barrier layer and a well layer, and is made of one or more materials selected from the group consisting of In, Ga, Al, As, P, and N. The barrier layer may have a four-layer structure including an AlGaInP layer with a thickness of 6 nm, for example. The well layer may have a three-layer structure including a GaInP layer with a thickness of 5 μm, for example. The active layer may be a single layer structure including (Al)GaInP or (Al)GaAs. The active layer may also be made of GaN, InGaN, AlGaN, or other nitride semiconductors.

The upper cladding layer 126 is a P-type cladding layer made of AlGaInP or AlGaAs with a thickness of 2.0 μm, for example.

The p-type contact layer 128 is made of GaAs with a thickness of 0.5 μm, for example.

Referring to FIG. 5B, a thermal oxide film (SiO₂ film) 129 is formed over the multi-layered growth layer 120 by the CVD (chemical vapor deposition) method. The thermal oxide film 129 is then patterned using a photoresist process to form an etching mask. The etching mask determines the shape of the ridge 150. In the emission area A1, the width of the etching mask, in other words, the width w₁ of the ridge 150_1 can be approximately set to 100 μm, for example. In the gain area A2, the width of the etching mask, in other words, the width w₂ of the ridge 150_2, is approximately set to 2 μm, for example; hence the relationship of these widths is expressed by w₁≈w₂×50. The length of the etching mask in the direction of the resonator in the emission area A1 is set to 10 μm, for example.

Referring to FIG. 5C, by chemical etching using HCl-based etchant or dry etching process, the thermal oxide film 129 is used as an etching mask to etch the upper cladding layer 126 from the p-type contact layer 128 to a depth halfway of the upper cladding layer 126. In dry etching, after the front surface of the p-type contact layer 128 is etched with an etchant containing H₂O₂, the thermal oxide film 129, which is a mask, is removed with HF-based etchant to remove the damaged layer on the surface. This undergoes ridge processing to form the ridge 150_1. The width w₁ of the ridge 150_1 is 100 μm, for example.

Referring to FIG. 5D, a mask (not shown) covering areas other than the emission area A1 is formed, and then the p-type contact layer 128 of the emission area A1 is removed by etching. When the insulating property against the gain area A2 has been secured, the p-type contact layer 128 of the emission area A1 may be left in place.

Referring to FIG. 5E, formed is the insulating film 134 containing at least one material selected from the group consisting of SiO₂, SiNₓ, SiON, Al₂O₃, AlN, AlON, Ta₂O₅, and ZrO₂. Thereafter, electrodes are formed.

The manufacturing method of the semiconductor laser device 100A has been described above.

The following is Variation Examples related to Embodiment 1.

### Variation Example 1.1

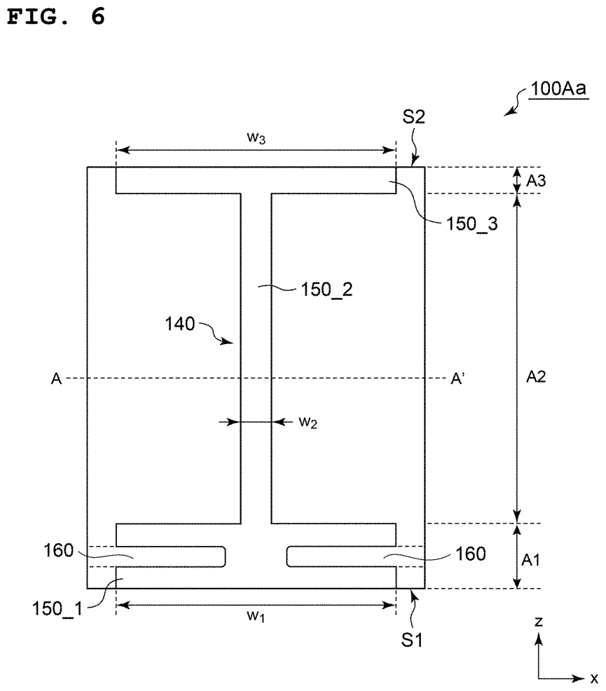

FIG. 6 is a plan view of a semiconductor laser device 100Aa according to Variation Example 1.1. In FIG. 2, the light-shielding groove 160 is formed to be kept away from the emission area A1, but in this Variation Example, the light-shielding groove 160 may be formed in the emission area A1.

### Variation Example 1.2

The light-shielding groove 160 may be omitted.

### Variation Example 1.3

In FIG. 2, the width w₁ of the ridge 150_1 may be equal to the width of the chip (semiconductor substrate 110). In this case, the width w₃ of the ridge 150_3 in the reflection area A3 may also be equal to the width of the chip.

### Embodiment 2

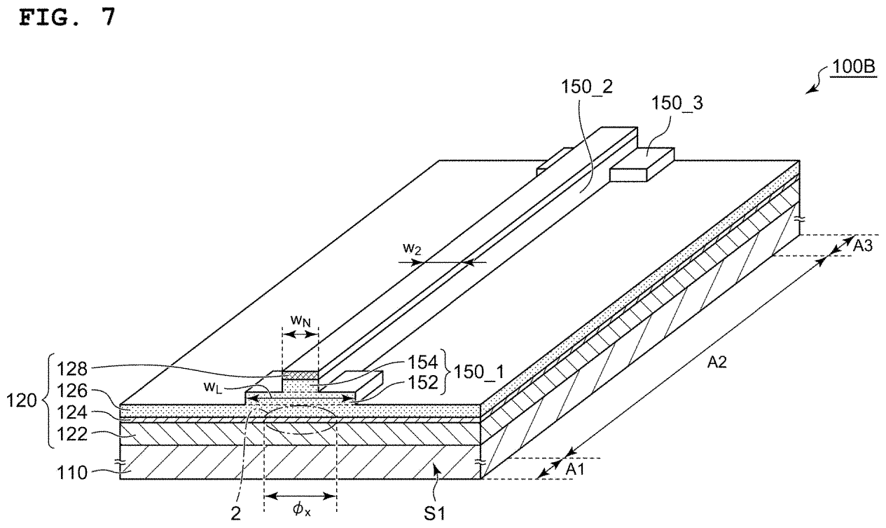

FIG. 7 is a perspective view of a semiconductor laser device 100B according to Embodiment 2. In Embodiment 2, the cross-sectional shape of the ridge 150_1 in the emission area A1 is different from that of Embodiment 1.

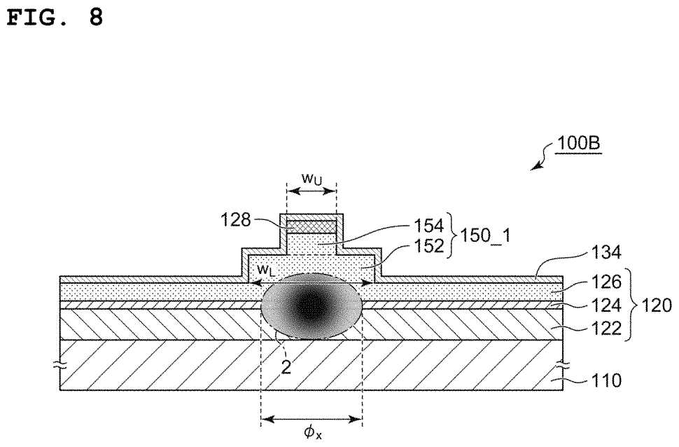

FIG. 8 is a front view of the semiconductor laser device 100B of FIG. 7 viewed from the emission end face S1. In Embodiment 2, when the emission end face S1 is viewed from the front, the width w_{U} of the upper end of the ridge 150_1 in the emission area A1 is narrower than the width w_{L} of the lower end thereof when the emission end face S1 is viewed in front.

Specifically, in Embodiment 2, when the emission end face S1 is viewed in front, the cross-sectional shape of the ridge 150_1 in the emission area A1 includes a lower rectangular portion 152 and an upper rectangular portion 154. The width w_{L} of the lower rectangular portion 152 is wider than the width w_{U} of the upper rectangular portion 154. The width w_{U} of the upper rectangular portion 154 is equal to the width w₂ of the ridge 150_2 in the gain area A2.

In Embodiment 2, as is similar to Embodiment 1, the width of the ridge 150_1 is extended in a manner that the virtual line 2 above the light-emitting layer 124 fits in the ridge 150_1 in the emission area A1. Specifically, the width w_{L} of the lower rectangular portion 152 in the emission area A1 is larger than the emission spot diameter ϕₓ (1/e₂ width).

The width w_{L} of the lower rectangular portion 152 is preferably w_{L}>3×ϕₓ because setting w_{L} to be larger further reduces the laser light leaking to the side face. Moreover, setting w_{L}>4×ϕₓ or w_{L}>5×ϕₓ will further reduce the leaked light.

The method of manufacturing the semiconductor laser device 100B according to Embodiment 2 is basically similar to the method of manufacturing the semiconductor laser device 100A according to Embodiment 1. In the method of manufacturing the semiconductor laser device 100B, etching the ridge 150_1 is modified in two steps.

The following is Variation Examples related to Embodiment 2.

### Variation Example 2.1

The light-shielding groove 160 may be added to the semiconductor laser device 100B of FIG. 7. In this case, the light-shielding groove 160 may be formed to be kept away from the emission area A1, as is similar to FIG. 2.

### Variation Example 2.2

In FIG. 7, the emission area A1 is a current non-injection area, and the p-type contact layer 128 is formed only in the gain area A2 and may not be formed in the emission area A1. In this case, as shown in FIG. 8, the p-type contact layer 128 on the upper side of the upper rectangular portion 154 of the ridge 150_1 is removed by etching.

### Embodiment 3

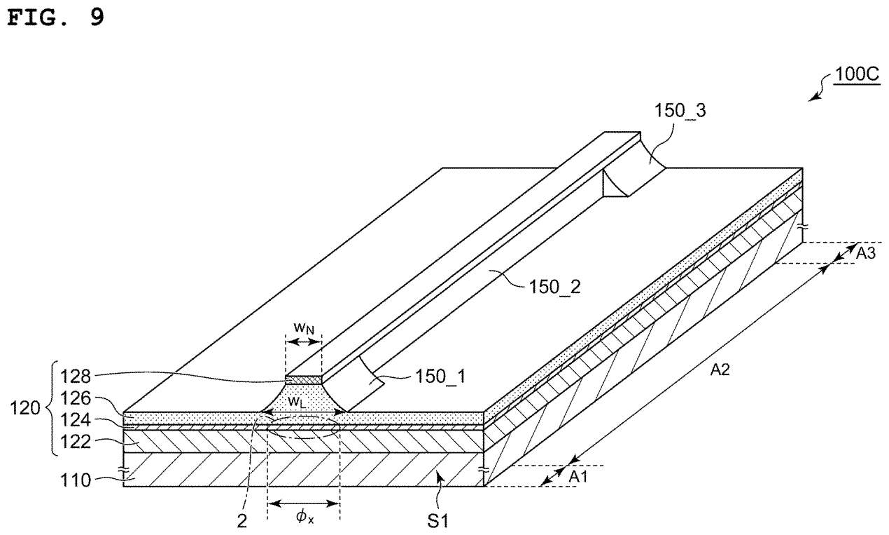

FIG. 9 is a perspective view of a semiconductor laser device 100C according to Embodiment 3. In Embodiment 3, as is similar to Embodiment 2, the width w_{U} of the upper end of the ridge 150_1 in the emission area A1 is narrower than the width w_{L} of the lower end thereof when the emission end face S1 is viewed in front; however, the cross-sectional shape of the ridge 150_1 is different from that of Embodiment 2.

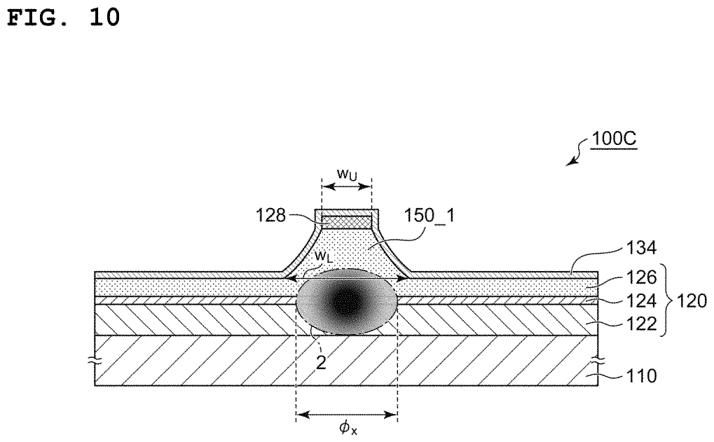

FIG. 10 is a front view of the semiconductor laser device 100C of FIG. 9 viewed from the emission end face S1. In Embodiment 3, when the emission end face S1 is viewed in front, the cross-sectional shape of the ridge 150_1 in the emission area A1 is tilted (tapered) from the lower end of the ridge 150_1 to the upper end thereof when the emitting end face S1 is viewed in front. The width w_{U} of the upper end is equal to the width w₂ of the ridge 150_2 in the gain area A2. The foot of ridge 150_1 may have a gentle curved line. Alternatively, the foot of the ridge 150_1 may have a straight line, and thus the cross-sectional shape of the ridge 150_1 may be trapezoidal.

In Embodiment 3, the width of the ridge 150_1 is extended in a manner that the virtual line 2 above the light-emitting layer 124 fits in the ridge 150_1 in the emission area A1. Specifically, the width (width at foot) w_{L} of the lower end of the ridge 150_1 is larger than the emission spot diameter ϕₓ (1/e₂ width). The width w_{L} of the lower end of the ridge 150_1 is preferably w_{L}>3×ϕₓ because setting the width w_{L} larger further reduces the laser light leaking to the side face. Moreover, setting w_{L}>4×ϕₓ or w_{L}>5×ϕₓ will further reduce the leaked light.

The cross-sectional shape of the ridge 150_1, i.e., the width w_{U} and height of the upper end, or in other words, the extent of the tilt, may be determined in a manner that the tilted portion of the ridge 150_1 does not intersect with the virtual line 2.

The method of manufacturing the semiconductor laser device 100C according to Embodiment 3 is basically similar to the method of manufacturing the semiconductor laser device 100A according to Embodiment 1. In the method of manufacturing the semiconductor laser device 100C, the slope of the ridge 150_1 can be formed using the isotropic nature of wet etching.

The following is Variation Examples related to Embodiment 3.

### Variation Example 3.1

The light-shielding groove 160 may be added to the semiconductor laser device 100C of FIG. 9. In this case, the light-shielding groove 160 may be formed to be kept away from the emission area A1, as is similar to FIG. 2.

### Variation Example 3.2

In FIG. 9, the emission area A1 is a current non-injection area, and the p-type contact layer 128 is formed only in the gain area A2 and may not be formed in the emission area A1. In this case, as shown in FIG. 10, the p-type contact layer 128 on the upper side of the ridge 150_1 is removed by etching.

### Embodiment 4

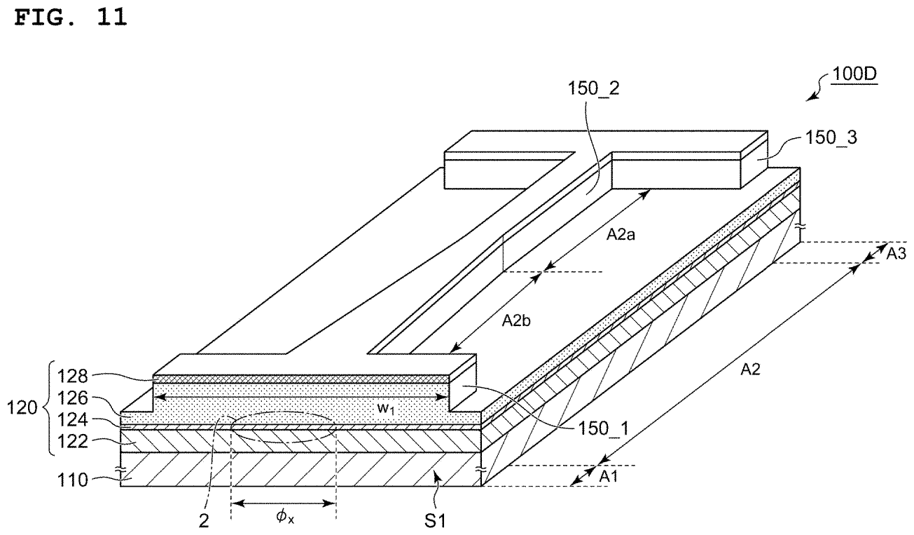

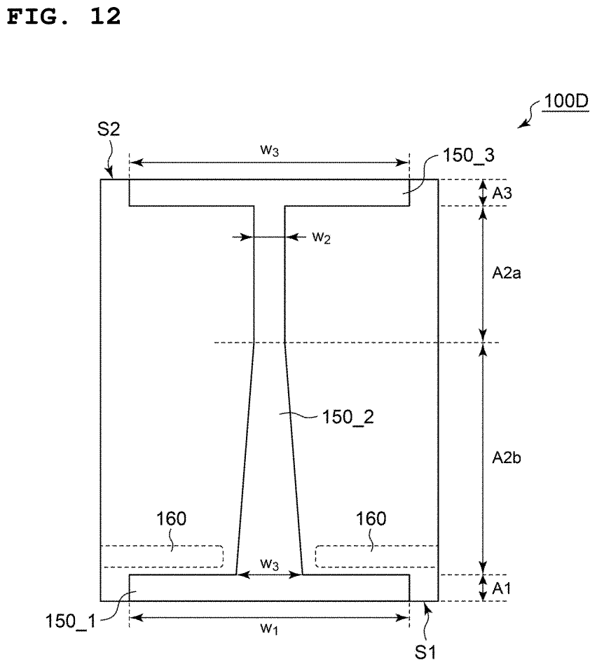

FIG. 11 is a perspective view of a semiconductor laser device 100D according to Embodiment 4. Note that the front view that is viewed from the emission end face S1 of Embodiment 4 shown in FIG. 11 has a similar shape as the front view shown in FIG. 3B. FIG. 12 is a plan view of the semiconductor laser device 100D shown in FIG. 11. In Embodiments 1 to 3, the ridge 150_2 in the gain area A2 has a constant width. However, in Embodiment 4, the ridge 150_2 has a tapered width when viewed in plan. The gain area A2 includes a straight portion A2a and a tapered portion A2b. In the gain area A2, the width w₂ of the straight portion A2a is constant, and the width of the tapered portion A2b increases from w₂ to w₃. The light-shielding groove 160 may be formed at location adjacent to the ridge 150_1.

Embodiment 4 can also have an effect similar to Embodiments 1-3.

The following is Variation Examples related to Embodiment 4.

### Variation Example 4.1

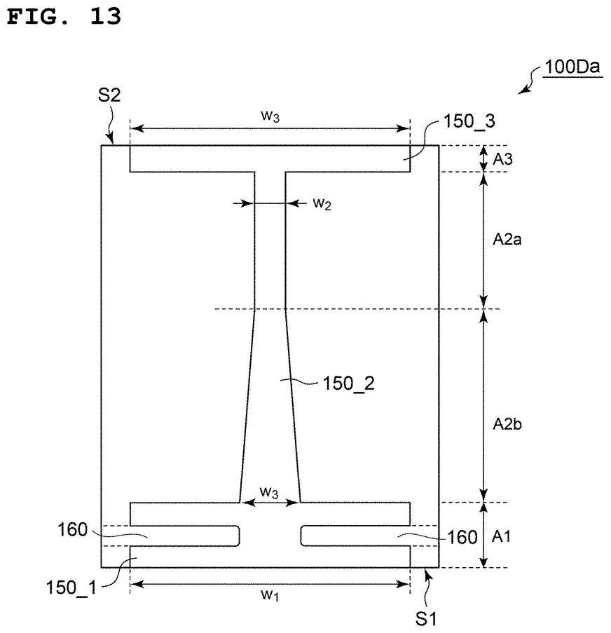

FIG. 13 is a plan view of a semiconductor laser device 100Da according to Variation Example 4.1. In this semiconductor laser device 100Da, the light-shielding groove 160 is formed at a location different from that in the semiconductor laser device 100D of FIG. 12. Specifically, as is similar to FIG. 6, the light-shielding groove 160 is formed in the emission area A1 in a manner that overlaps the ridge 150_1.

### Variation Example 4.2

In FIG. 11, the emission area A1 is a current non-injection area, and the p-type contact layer 128 is formed only in the gain area A2 and may not be formed in the emission area A1. In this case, the p-type contact layer 128 on the upper side of the ridge 150_1 is removed by etching, thus the plan view of FIG. 11 is similar to FIG. 3B.

### Variation Example 4.3

The shape of the gain area A2 is not limited to that shown in FIG. 12. For example, the straight portion Ata can be omitted and the tapered portion A2b can be entirely formed in the gain area A2. The emission area A1 may be formed with a shape in which the tapered portion A2b is simply extended toward the emission end face S1.

### Embodiment 5

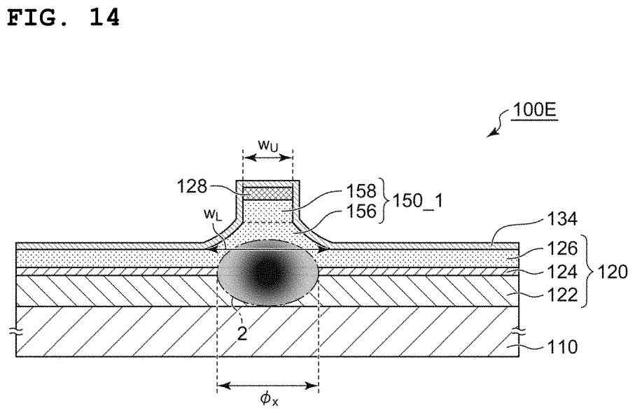

FIG. 14 is a front view of a semiconductor laser device 100E according to Embodiment 5 when viewed from the emission end face S1.

In embodiment 5, the cross-sectional shape of the ridge 150_1 in the emission area A1 includes a trapezoidal portion 156 and a rectangular portion 158. The trapezoidal portion 156 is tilted (tapered) from its upper end to its lower end. The slope (foot) of the trapezoidal portion 156 may vary gently. The width w_{U} of the upper end is equal to the width w₂ of the ridge 150_2 in the gain area A2.

The cross-sectional shape of the trapezoidal portion 156 of the ridge 150_1, i.e., the width of the upper end w_{U} and the height, in other words, the extent of the tilt, is determined in a manner that the tilted portion of the trapezoidal portion 156 does not intersect with the virtual line 2.

Finally, Variation Examples related to the whole will be described.

### Variation Example 1

In Embodiments 1 to 4, the case in which the side faces of the ridge 150 are covered with the insulating film 134; however, the present disclosure is not limited to the case. Even in the case in which the insulating film 134 is absent, the presence of a void, a metal layer, or other materials adjacent to the ridge 150 can cause light leaking from the ridge 150 to emit from the area adjacent to the ridge 150, generating interference fringes. Hence, the technique of widening the width of the ridge 150_1 in the emission area A1 can be applied regardless of the presence or absence of the insulating film 134.

### Variation Example 2

The cross-sectional shape of the ridge 150_1 in the emission area A1 is not limited to those described in the embodiments; the virtual line indicating 1/e₂ of the peak intensity can be spread out in a shape that fits inside the upper cladding layer 126.

### Variation Example 3

A bank may be formed in the upper cladding layer 126 adjacent to the ridge 150. The bank is formed on each of both side faces of the ridge 150 over the entire length in the direction of the resonator to protect the ridge 150 and the like. The bank can have the same height (thickness in the y direction) as that of the ridge 150.

### Variation Example 5

The application of the semiconductor laser device 100 is not limited to laser pointers, but can also be used for levelers, rangefinders, sensors, light sources for projectors, etc.

In the case of focusing the light emitted from the semiconductor laser device 100 for use, a poor beam profile makes the minimum spot diameter large. According to the present embodiment, it is also possible to reduce the minimum spot diameter in the case of focusing the light emitted from the semiconductor laser device 100, making the semiconductor laser device applicable to optical disk pickups, for example.

The embodiments merely show the principles and applications of the present disclosure or invention, and many variation examples and modifications in the arrangement are allowed for the present embodiment to the extent that does not depart from the idea of the disclosure or invention stipulated in the scope of the claims.

What is claimed is:

1. A semiconductor laser device is an edge-emitting semiconductor laser device, the semiconductor laser device comprising:
a laser resonator including a layered structure in which a lower cladding layer, an active layer, and an upper cladding layer are formed over a semiconductor substrate, and a ridge that is formed on the upper cladding layer, the laser resonator emitting laser light having a beam profile,
wherein when viewed in plan from a direction orthogonal to the semiconductor substrate, the laser resonator includes an emission area on its emission end face,
wherein when the emission end face of the laser resonator is viewed in front, a virtual line defined by an intensity being 1/e₂ of a peak intensity of the beam profile of the laser light fits inside the upper cladding layer in the emission area.

2. The semiconductor laser device according to claim 1, wherein when the semiconductor laser device is viewed in plan from a direction orthogonal to the semiconductor substrate, a width of the ridge widens at a boundary of the emission area.

3. The semiconductor laser device according to claim 1, wherein at least a side face of the ridge is covered with an insulating layer.

4. The semiconductor laser device according to claim 1, wherein when the emission end face is viewed in front, a cross-sectional shape of the ridge in the emission area is rectangular, and the width of the ridge is larger than a 1/e² width of the beam profile in a lateral direction.

5. The semiconductor laser device according to claim 4, wherein the width of the ridge is three times or more as large as the 1/e² width of the beam profile in the lateral direction.

6. The semiconductor laser device according to claim 1, wherein when the emission end face is viewed in front, a width of an upper end of the ridge in the emission area is narrower than a width of a lower end thereof.

7. The semiconductor laser device according to claim 6, wherein when the emission end face is viewed in front, the cross-sectional shape of the ridge in the emission area has a lower rectangular portion having a first width, and an upper rectangular portion having a second width narrower than the first width and being adjacent to and above the lower rectangular portion, and
wherein the first width is larger than the 1/e² width of the beam profile in the lateral direction.

8. The semiconductor laser device according to claim 7, wherein the first width is three times or more as large as the 1/e² width of the beam profile in the lateral direction.

9. The semiconductor laser device according to claim 6, wherein when the emission end face is viewed in front, the cross-sectional shape of the ridge in the emission area is tilted from the upper end to the lower end.

10. The semiconductor laser device according to claim 3, wherein the insulating layer includes at least one material selected from a group consisting of SiO₂, SiNₓ, SiON, Al₂O₃, AlN, AlON, Ta₂O₅, and ZrO₂.

11. The semiconductor laser device according to claim 1, wherein the active layer includes at least one material selected from a group consisting of In, Ga, Al, As, P, and N.

12. The semiconductor laser device according to claim 1, wherein when the semiconductor laser device is viewed in plan from a direction orthogonal to the semiconductor substrate, the laser resonator includes a gain area adjacent to the emission area, and
the ridge in the gain area of the laser resonator is designed such that the laser light has a transverse single mode.

13. The semiconductor laser device according to claim 1, wherein a light-shielding groove is formed at a location adjacent to the emission area, the light-shielding groove extending in a direction orthogonal to the laser resonator.

14. The semiconductor laser device according to claim 1, wherein a light-shielding groove is formed in the emission area, the light-shielding groove extending in a direction orthogonal to the laser resonator.

15. A semiconductor laser device is an edge-emitting semiconductor laser device, the semiconductor laser device comprising:
a laser resonator including a layered structure in which a lower cladding layer, an active layer, and an upper cladding layer are formed over a semiconductor substrate; and
a ridge that is formed on the upper cladding layer,
wherein when viewed in plan from a direction orthogonal to the semiconductor substrate, the laser resonator includes an emission area on its emission end face and a gain area adjacent to the emission area,
a width of the ridge widens stepwise at a boundary between the gain area and the emission area, and
a width of the ridge in the emission area is three times or more as large as a maximum width of the ridge in the gain area.

16. A method of manufacturing an edge-emitting semiconductor laser device, the method comprising:
forming a layered structure including a lower cladding layer, an active layer, and an upper cladding layer over a semiconductor substrate;
undergoing ridge processing in the upper cladding layer in a manner that, when an emission end face of the semiconductor laser device is viewed in front, a virtual line defined by an intensity being 1/e₂ of a peak intensity of a beam profile of laser light fits inside the upper cladding layer in an emission area of a laser resonator; and
forming an insulating layer covering at least a side face of a ridge that has been formed on the upper cladding layer by the ridge processing.
